(19) United States
(12) Patent Application Publication
(10) Pub. No.: US 2023/0072728 A1
(43) Pub. Date: Mar. 9, 2023

(54) SUBSTRATE TREATING APPARATUS AND SUBSTRATE TREATING METHOD USING THE SAME

(71) Applicant: SEMES CO., LTD., Chungcheongnam-do (KR)

(72) Inventors: Jae Seong LEE, Gyeonggi-do (KR); Jung Suk GOH, Gyeonggi-do (KR); Hae Won CHOI, Daejeon (KR)

(21) Appl. No.: 17/737,345

(22) Filed: May 5, 2022

(30) Foreign Application Priority Data
Sep. 8, 2021 (KR) 10-2021-0119414

(51) Int. Cl. H01L 21/67; H01L 21/02

(52) U.S. Cl. CPC H01L 21/67034; H01L 21/02052

(57) ABSTRACT

The present disclosure provides a substrate treating apparatus, in which stability is secured by performing a process under a lower pressure condition, and a substrate treating method using the same. The substrate treating apparatus comprises a chamber including a housing and a treating region, wherein a substrate on which a rinse liquid remains is loaded into the chamber, a supply port installed in the housing and for supplying a first drying gas and a second drying gas to the treating region, a first supply line connected to the supply port, and through which the first drying gas is moved, and a second supply line connected to the supply port, and through which the second drying gas is moved, wherein the first drying gas is a gas below a first temperature, and the second drying gas is a gas equal to or above the first temperature, wherein the second drying gas dries the rinse liquid remaining on the substrate.

This application claims the benefit of Korean Patent Application No. 10-2021-0119414, filed on Sep. 8, 2021, in the Korean Intellectual Property Office, the disclosure of which is incorporated herein by reference in its entirety.

### BACKGROUND

### 1. Field

The present disclosure relates to a substrate treating apparatus and a substrate treating method using the same.

### 2. Description of the Related Art

As semiconductor devices become high-density, high-integration, and high-performance, circuit pattern miniaturization is rapidly progressing, so that contaminants such as particles, organic contaminants, and metal contaminants remaining on the substrate surface have a great influence on device characteristics and production yield. Accordingly, a cleaning process that removes various contaminants attached to the substrate surface has become very important in the semiconductor device manufacturing process, and a cleaning process of cleaning the substrate is performed before and after each unit process of manufacturing a semiconductor device.

Recently, a supercritical drying process of drying a substrate using a supercritical fluid has been used. The supercritical drying process is performed under high pressure and high temperature conditions, and thus may be vulnerable in terms of stability.

### SUMMARY

An object of the present disclosure is to provide a substrate treating apparatus, in which stability is secured by performing a process under a relatively low pressure condition, and a substrate treating method using the same.

The objects of the present disclosure are not limited to the objects mentioned above, and other objects not mentioned will be clearly understood by those skilled in the art from the following description.

One aspect of the substrate treating apparatus of the present disclosure for achieving the above object comprises a chamber including a housing and a treating region, wherein a substrate on which a rinse liquid remains is loaded into the chamber; a supply port installed in the housing and for supplying a first drying gas and a second drying gas to the treating region; a first supply line connected to the supply port, and through which the first drying gas is moved; and a second supply line connected to the supply port, and through which the second drying gas is moved, wherein the first drying gas is a gas below a first temperature, and the second drying gas is a gas equal to or above the first temperature, wherein the second drying gas dries the rinse liquid remaining on the substrate.

The substrate treating apparatus supplies the first drying gas to the treating region when the pressure in the treating region is lower than a preset pressure, and supplies the second drying gas to the treating region when the pressure in the treating region is equal to or greater than the preset pressure.

Wherein the preset pressure is 10 bar or more and 40 bar or less.

Wherein the first drying gas does not dry the rinse liquid.

Wherein the first temperature is 150 degrees or more and 250 degrees or less.

Wherein a surface tension between the rinse liquid and the first drying gas is greater than 5 dyn/cm, and a surface tension between the rinse liquid and the second drying gas is 5 dyn/cm or less.

Wherein the supply port comprises a first supply port connected to the first supply line, and a second supply port connected to the second supply line, the first drying gas is supplied to the treating region through the first supply port, and wherein the second drying gas is supplied to the treating region through the second supply port.

The substrate treating apparatus further comprises a storage unit connected to the first supply line and the second supply line, and a heating member installed in the second supply line and for increasing a temperature of the second drying gas.

Another aspect of the substrate treating apparatus of the present disclosure for achieving the above object comprises a chamber including a housing and a treating region, wherein a substrate on which a rinse liquid remains is loaded into the chamber; a supply port installed in the housing and for supplying a first drying gas and a second drying gas that are in a gaseous state to the treating region; a first supply line connected to the supply port, and through which the first drying gas is moved; and a second supply line connected to the supply port, and through which the second drying gas is moved, wherein a surface tension between the rinse liquid and the first drying gas is greater than 5 dyn/cm, and a surface tension between the rinse liquid and the second drying gas is less than 5 dyn/cm.

The substrate treating apparatus supplies the first drying gas until a pressure in the treating region reaches a preset pressure, and supplies the second drying gas in response to the pressure in the treating region reaching the preset pressure.

Wherein the preset pressure is 10 bar or more and 40 bar or less.

The sub state treating apparatus dries the rinse liquid applied on the substrate by using the second drying gas.

Wherein the first drying gas is a CO₂ gas that is less than a first temperature, and the second drying gas is a CO₂ gas that is higher than the first temperature.

Wherein the first temperature is 150 degrees or more and 250 degrees or less.

Wherein the supply port comprises a first supply port connected to the first supply line, and a second supply port connected to the second supply line, wherein the first drying gas is supplied to the treating region through the first supply port, wherein the second drying gas is supplied to the treating region through the second supply port.

The substrate treating apparatus further comprises a storage unit connected to the first supply line and the second supply line; and a heating member installed in the second supply line and for increasing a temperature of the second drying gas.

Wherein the storage unit comprises a first storage unit connected to the first supply line and for storing the first drying gas, and a second storage unit connected to the second supply line and for storing the second drying gas.

One aspect of the substrate treating method of the present disclosure for achieving the above object comprises loading a substrate with a rinse liquid remaining into a chamber; supplying a first drying gas into the chamber to increase a pressure in the chamber; stopping the supply of the first drying gas, and supplying a second drying gas different from the first drying gas in response to the pressure in the chamber reaching a preset pressure; and drying the rinse liquid on the substrate using the second drying gas, wherein the second drying gas is a gas having a temperature of 150 degrees or more and 250 degrees or less, wherein a surface tension between the rinse liquid and the second drying gas is 5 dyn/cm or less.

Wherein the preset pressure is 10 bar or more and 40 bar or less.

Wherein the first drying gas is a gas of less than 150 degrees, and a surface tension between the first drying gas and the rinse liquid is greater than 5 dyn/cm.

Wherein the first drying gas is supplied into the chamber through a first supply port, and the second drying gas is supplied into the chamber through a second supply port different from the first supply port.

The details of other embodiments are included in the detailed description and drawings.

### BRIEF DESCRIPTION OF THE DRAWINGS

These and/or other aspects will become apparent and more readily appreciated from the following description of the embodiments, taken in conjunction with the accompanying drawings in which:

FIG. 1 is a plan view for describing a substrate treating apparatus according to some embodiments of the present disclosure;

FIGS. 2 to 4 are exemplary cross-sectional views for describing a substrate treating apparatus according to some embodiments;

FIGS. 5 to 7 are graphs for describing a substrate treating apparatus according to some embodiments;

FIGS. 8 and 9 are graphs for describing a drying gas according to some embodiments;

FIG. 10 is a flowchart illustrating a substrate treating method according to some embodiments;

FIG. 11 is an exemplary diagram for describing step S100 of FIG. 10;

FIGS. 12a to 13 are exemplary views for describing step S200 of FIG. 10; and

FIGS. 14a to 15 are exemplary views for describing steps S300 and S400 of FIG. 10.

### DETAILED DESCRIPTION

Hereinafter, preferred embodiments of the present disclosure will be described in detail with reference to the accompanying drawings. Advantages and features of the present disclosure and methods of achieving them will become apparent with reference to the embodiments described below in detail in conjunction with the accompanying drawings. However, the present disclosure is not limited to the embodiments described below, but may be implemented in various different forms, and these embodiments are provided only for making the description of the present disclosure complete and fully informing those skilled in the art to which the present disclosure pertains on the scope of the present disclosure, and the present disclosure is only defined by the scope of the claims. Like reference numerals refer to like elements throughout.

When an element or layer is referred as being located “on” another element or layer, it includes not only being located directly on the other element or layer, but also with intervening other layers or elements. On the other hand, when an element is referred as being “directly on” or “immediately on,” it indicates that no intervening element or layer is interposed.

Spatially relative terms “below,” “beneath,” “lower,” “above,” and “upper” can be used to easily describe a correlation between an element or components and other elements or components. The spatially relative terms should be understood as terms including different orientations of the device during use or operation in addition to the orientation shown in the drawings. For example, when an element shown in the figures is turned over, an element described as “below” or “beneath” another element may be placed “above” the other element. Accordingly, the exemplary term “below” may include both directions below and above. The device may also be oriented in other orientations, and thus spatially relative terms may be interpreted according to orientation.

Although first, second, etc. are used to describe various elements, components, and/or sections, it should be understood that these elements, components, and/or sections are not limited by these terms. These terms are only used to distinguish one element, component, or section from another element, component, or section. Accordingly, the first element, the first component, or the first section mentioned below may be the second element, the second component, or the second section within the technical spirit of the present disclosure.

The terminology used herein is for the purpose of describing the embodiments and is not intended to limit the present disclosure. In the present disclosure, the singular also includes the plural, unless specifically stated otherwise in the phrase. As used herein, “comprises” and/or “comprising” refers to that components, steps, operations and/or elements mentioned does not exclude the presence or addition of one or more other components, steps, operations and/or elements.

Unless otherwise defined, all terms (including technical and scientific terms) used herein may be used with the meaning commonly understood by those of ordinary skill in the art to which the present disclosure belongs. In addition, terms defined in a commonly used dictionary are not to be interpreted ideally or excessively unless clearly defined in particular.

Hereinafter, embodiments of the present disclosure will be described in detail with reference to the accompanying drawings, and in the description with reference to the accompanying drawings, the same or corresponding components are given the same reference numbers, regardless of reference numerals in drawings, and an overlapped description therewith will be omitted.

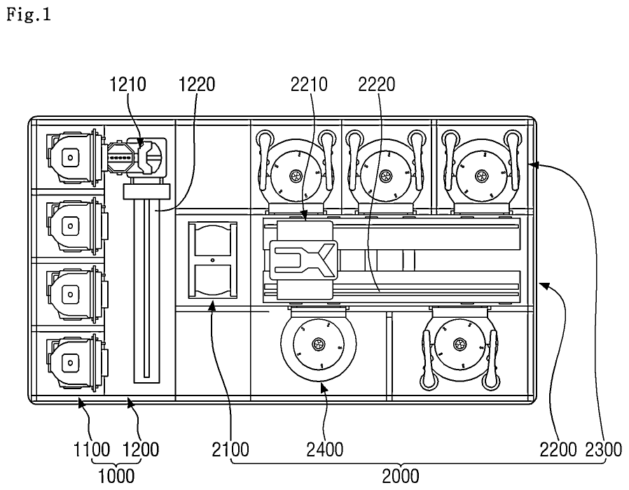

Hereinafter, a substrate treating apparatus according to some embodiments of the present disclosure will be described with reference to FIGS. 1 to 9.

FIG. 1 is a plan view for describing a substrate treating apparatus according to some embodiments of the present disclosure.

Referring to FIG. 1, the substrate treating apparatus may include an index module 1000 and a process module 2000.

The index module 1000 receives the substrate from the outside and transfers the substrate to the process module 2000. The process module 2000 may perform a cleaning process and a drying process. The index module 1000 may be an equipment front end module (EFEM). The index module 1000 may include a load port 1100 and a transfer frame 1200.

The load port 1100 may receive a substrate. A substrate may be placed in a container within the load port 1100. As the container, a front opening unified pod (FOUP) may be used. The container may be loaded into the load port 1100 from the outside by an overhead transfer (OHT). The container may be carried out from the load port 1100 to the outside by an overhead transfer. The transfer frame 1200 may transfer the substrate between the container placed on the load port 1100 and the process module 2000.

The process module 2000 may be a module that actually performs a process. The process module 2000 may include a buffer chamber 2100, a transfer chamber 2200, a first process chamber 2300, and a second process chamber 2400.

The buffer chamber 2100 provides a space, in which a substrate transferred between the index module 1000 and the process module 2000 temporarily stays. The buffer chamber 2100 may provide a buffer slot, in which a substrate is placed. The transfer robot 2210 of the transfer chamber 2200 may carries out the substrate placed in the buffer slot and transfer it to the first process chamber 2300 or the second process chamber 2400. The buffer chamber 2100 may provide a plurality of buffer slots.

The transfer chamber 2200 transfers a substrate between the buffer chamber 2100, the first process chamber 2300, and the second process chamber 2400 arranged around the transfer chamber 2200. The transfer chamber 2200 may include a transfer robot 2100 and a transfer rail 2220. The transfer robot 2210 may move on the transfer rail 2220 and transfer the substrate.

In some embodiments, the first process chamber 2300 and the second process chamber 2400 may perform a cleaning process. The cleaning process may be sequentially performed in the first process chamber 2300 and the second process chamber 2400. In another embodiment, a cleaning process may be performed in the first process chamber 2300 and a drying process may be performed in the second process chamber 2400.

The first process chamber 2300 may be arranged at one side of the transfer chamber 2200. The second process chamber 2400 may be arranged at the other side of the transfer chamber 2200. That is, the first process chamber 2300 and the second process chamber 2400 may be arranged on different sides of the transfer chamber 2200 to face each other.

A plurality of first process chambers 2300 and second process chambers 2400 may be provided in the process module 2000. The plurality of first process chambers 2300 may be arranged in a line at one side of the transfer chamber 2200. However, the technical spirit of the present disclosure is not limited thereto.

The arrangement of the first process chamber 2300 and the second process chamber 2400 is not limited to the above-described example, and may be changed in consideration of a footprint or process efficiency of a substrate treating apparatus.

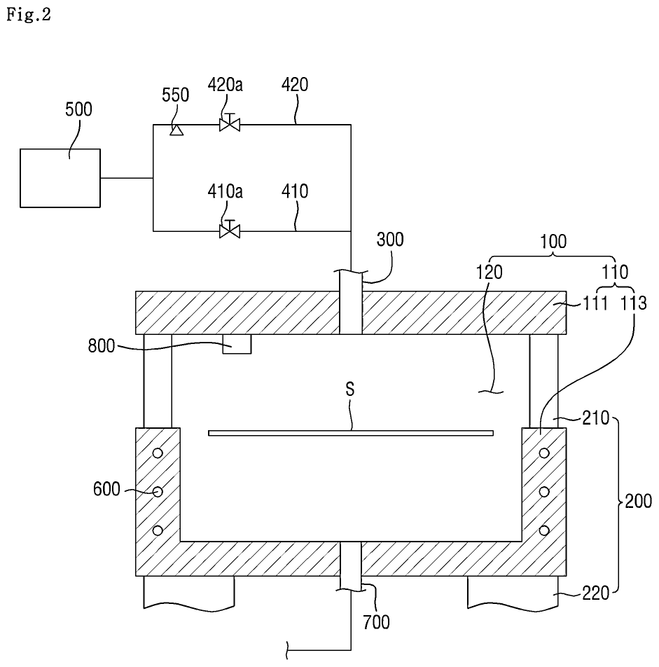

FIGS. 2 to 4 are exemplary cross-sectional views for describing a substrate treating apparatus according to some embodiments. For reference, FIGS. 2 to 4 may be views illustrating the second process chamber 2400 of FIG. 1. The substrate treating apparatus according to some embodiments may perform a drying process using gaseous carbon dioxide as a process gas.

Referring to FIG. 2, a substrate treating apparatus according to some embodiments may include a chamber 100, a lifting unit 200, a supply port 300, a first supply line 410, and a second supply line 420.

The chamber 100 may include a housing 110 and a treating region 120. The treating region 120 may be a space, in which various semiconductor processes are performed. The substrate S may be loaded into the treating region 120. A semiconductor process may be performed on the substrate S loaded into the treating region 120. For example, at least one of a cleaning process, a drying process, and an etching process may be performed on the substrate S. In this disclosure, it will be described that the drying process is performed on the substrate S.

The housing 110 includes an upper housing 111 and a lower housing 113. The lower housing 113 is provided in coupled with the upper housing 111 under the upper housing 111. As such, the chamber 100 may have a structure divided into an upper portion and a lower portion. The space generated by the combination of the upper housing 111 and the lower housing 113 is provided as the treating region 120, in which a drying process is performed. The housing 110 is provided with a material that can withstand high pressure.

The upper housing 111 may be fixed by an external structure. The lower housing 113 may not be fixed. The lower housing 113 may be provided to be liftable with respect to the upper housing 111. When the lower housing 113 is lowered and spaced apart from the upper housing 111, the treating region 120 is opened. The substrate S may be loaded into the open treating region 120. The substrate S loaded into the treating region 120 may be a substrate, on which a rinse liquid remains. For example, a rinse liquid may be applied to the substrate S in the first process chamber (2300 of FIG. 1), and the substrate S, on which the rinse liquid remains, may be transferred to the second process chamber (2400 of FIG. 1).

When the lower housing 113 is lifted and coupled to the upper housing 111, the treating region 120 of the chamber 100 may be sealed. A drying process may be performed inside the sealed chamber 100.

However, the technical spirit of the present disclosure is not limited thereto, and the housing 110 may be provided in a structure, in which the lower housing 113 is fixed and the upper housing 111 is raised or lowered.

The lifting unit 200 may raise or lower the lower housing 113 in a vertical direction. The lifting unit 200 may include a lifting cylinder 220 and a lifting rod 210. The lifting cylinder 220 may generate a driving force sufficient to seal the chamber 100 by overcoming a high pressure inside the chamber 100 while the substrate drying process is performed using the gas. One end of the lifting rod 210 may be inserted into the lifting cylinder 220 to extend in a vertical direction. The other end of the lifting rod 210 may extend in a vertical direction to be coupled to the upper housing 111.

The supply port 300 may be installed in the housing 110. For example, the supply port 300 may be installed in the upper housing 111. The supply port 300 may supply the drying gas into the chamber 100. The supply port 300 may supply a precursor gas to the treating region 120. The drying gas may be a gas that increases the pressure in the treating region 120, and may be a gas capable of drying the rinse liquid remaining on the substrate S. The drying gas may be, for example, gaseous carbon dioxide.

Carbon dioxide may exist in a supercritical state when it has a temperature of 40 degrees or more at a pressure of about 75 bar or more. Drying gas is carbon dioxide having a temperature of 250 degrees or less at a pressure of 40 bar or less. Carbon dioxide may exist in a gaseous state when it has a temperature of 250 degrees or less at a pressure of 40 bar or less. Accordingly, the drying gas may be gaseous carbon dioxide.

The drying gas may include a first drying gas and a second drying gas. The first drying gas may be a drying gas for increasing the pressure in the treating region 120 to a preset pressure. The first drying gas may be a carbon dioxide gas having a temperature lower than the first temperature at a pressure of 40 bar or less. The surface tension between the rinse liquid and the first drying gas may be greater than 5 dyn/cm.

The second drying gas may be a carbon dioxide gas having a temperature equal to or higher than the first temperature at a pressure of 40 bar or less. The first temperature may be 150 degrees or more and 250 degrees or less, but is not limited thereto.

The rinse liquid remaining on the substrate S may be dried using the second drying gas. The surface tension between the rinse liquid and the second drying gas may be less than 5 dyn/cm. The surface tension between supercritical carbon dioxide and the rinse liquid is less than 5 dyn/cm. The second drying gas may be in a gaseous state and have conditions similar to those of supercritical carbon dioxide in performing a drying process. That is, when the substrate treating apparatus according to some embodiments is used, the process may be safely performed under a lower pressure condition than when supercritical carbon dioxide is used.

The first supply line 410 may be connected to the supply port 300. The first supply line 410 may be a passage, through which the first drying gas is moved. The first drying gas may be moved through the first supply line 410 and may be supplied to the treating region 120 through the supply port 300.

In some embodiments, the substrate treating apparatus may further include a first supply valve 410a connected to the first supply line 410. The first supply valve 410a may adjust the flow rate of the first drying gas moved through the first supply line 410. For example, when the first supply valve 410a is opened, the first drying gas is supplied to the treating region 120 through the first supply line 410. When the first supply valve 410a is closed, the first drying gas is not supplied to the treating region 120.

The second supply line 420 may be connected to the supply port 300. The second supply line 420 may be a passage, through which the second drying gas is moved. The second drying gas may be moved through the second supply line 420 and may be supplied to the treating region 120 through the supply port 300.

In some embodiments, the substrate treating apparatus may further include a second supply valve 420a connected to the second supply line 420. The second supply valve 420a may adjust the flow rate of the second drying gas moved through the second supply line 420. For example, when the second supply valve 420a is opened, the second drying gas is supplied to the treating region 120 through the second supply line 420. When the second supply valve 420a is closed, the second drying gas is not supplied to the treating region 120.

In some embodiments, the first supply line 410 and the second supply line 420 may be connected to one supply port 300, but is not limited thereto.

In some embodiments, the substrate treating apparatus may further include a storage unit 500 configured to store the first drying gas and the second drying gas. The storage unit 500 may be connected to the first supply line 410 and the second supply line 420. The first drying gas may be moved through the first supply line 410. The second drying gas may be moved through the second supply line 420.

In some embodiments, the substrate treating apparatus may further include a heating member 550 installed on the second supply line 420. The heating member 550 may adjust the temperature of the second drying gas moved to the second supply line 420. The second drying gas should be maintained at or above the first temperature. Accordingly, the heating member 550 may serve to maintain the temperature of the second drying gas above the first temperature.

In some embodiments, the substrate treating apparatus may further include a heating unit 600. The heating unit 600 may heat the inside of the chamber 100. The heating unit 600 may adjust the temperature inside the chamber 100. The heating unit 600 may heat the carbon dioxide gas supplied into the chamber 100 to a first temperature or higher. The first temperature may be 150 degrees or more and 250 degrees or less. The heating unit 600 may be installed by being buried in at least one wall of the upper housing 111 and the lower housing 113.

In some embodiments, the substrate treating apparatus may further include an exhaust member 700. The exhaust member 700 may exhaust gas in the chamber 100, for example, a drying gas to the outside of the chamber 100. The exhaust member 700 may be installed in the lower housing 113, but is not limited thereto.

In some embodiments, the substrate treating apparatus may further include a pressure measuring unit 800. The pressure measuring unit 800 may measure the pressure inside the chamber 100. The pressure measuring unit 800 may measure the pressure of a gas in the treating region 120, for example, a drying gas.

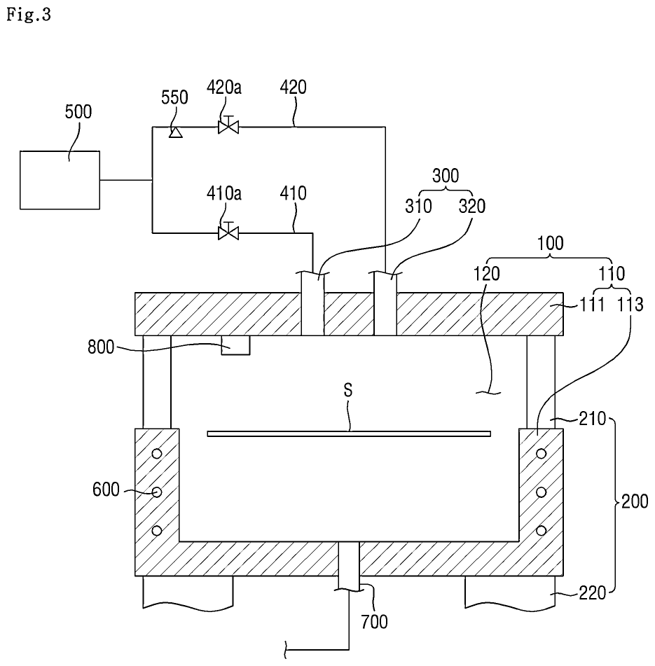

Referring to FIG. 3, the supply port 300 may include a first supply port 310 and a second supply port 320.

The first supply port 310 and the second supply port 320 may be installed to be spaced apart from each other. For example, the first supply port 310 may be installed in the upper housing 111. The second supply port 320 may be spaced apart from the first supply port 310 in the horizontal direction, and may be installed in the upper housing 111.

The first supply port 310 may be connected to the first supply line 410. The first drying gas may be supplied to the treating region 120 through the first supply port 310. The second supply port 320 may be connected to the second supply line 420. The second drying gas may be supplied to the treating region 120 through the second supply port 320. The first supply line 410 and the second supply line 420 are not connected to each other.

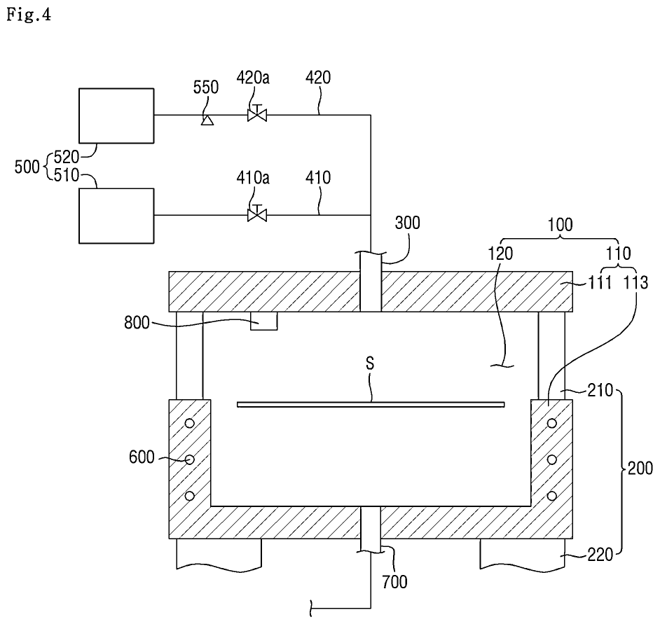

Referring to FIG. 4, the storage unit 500 may include a first storage unit 510 and a second storage unit 520.

The first storage unit 510 may be a space, in which the first drying gas is stored. The second storage unit 520 may be a space, in which the second drying gas is stored. The first storage unit 510 may be connected to the first supply line 410. The second storage unit 520 may be connected to the second supply line 420.

Although not shown, the heating member 550 may be connected to the second storage unit 520. The heating member 550 may adjust the temperature of the second drying gas stored in the second storage unit 520.

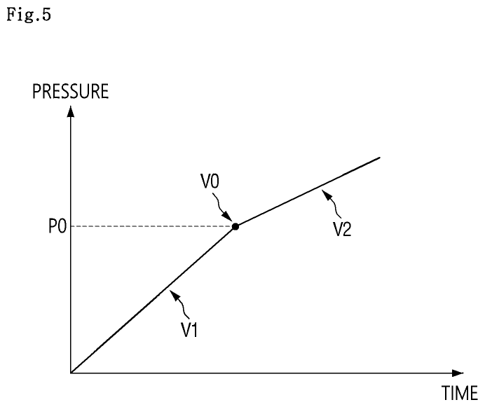

FIGS. 5 to 7 are graphs for describing a substrate treating apparatus according to some embodiments. For reference, FIGS. 5 to 7 are graphs showing the pressure in the chamber over time.

Referring to FIGS. 2 and 5, the pressure in the chamber 100 may gradually increase over time. The pressure within the treating region 120 gradually increases over time.

The graph includes a first section V1, a second section V2, and an intersection region V0 where the first section V1 and the second section V2 intersect. The first section V1 may be a section, in which the first drying gas is supplied into the chamber 100. The second section V2 may be a section, in which the second drying gas is supplied into the chamber 100. The intersection region V0 may be a region, in which the first supply valve 410a is closed and the second supply valve 420a is opened. That is, the intersection region V0 may be a point, at which the supply of the first drying gas is stopped and the supply of the second drying gas is started.

In the first section V1, the first supply valve 410a may be in an open state. As the first drying gas is supplied to the treating region 120, the pressure in the treating region 120 may gradually increase. In this case, the first drying gas may be a carbon dioxide gas having a temperature lower than the first temperature.

When the pressure in the treating region 120 reaches the preset pressure P0, the supply of the first drying gas may be stopped. When the pressure in the treating region 120 reaches the preset pressure P0, the first supply valve 410a may be closed. The preset pressure P0 may be, for example, 40 bar or less. Preferably, the preset pressure P0 may be 10 bar or more and 40 bar or less. However, the technical spirit of the present disclosure is not limited thereto.

When the pressure in the treating region 120 reaches the preset pressure P0, the second supply valve 420a may be opened. When the pressure in the treating region 120 reaches the preset pressure P0, the supply of the second drying gas may be started.

In the second section V2, the second supply valve 420a may be in an open state. The first supply valve 410a may be in a closed state. As the second drying gas is supplied into the treating region 120, the pressure in the treating region 120 may gradually increase.

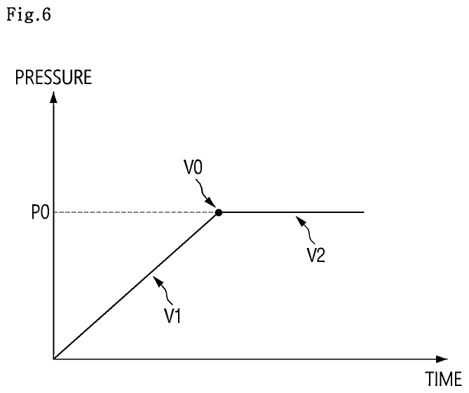

Referring to FIG. 6, in the second section V2, the pressure in the treating region 120 may be constantly maintained.

In the second section V2, a second drying gas may be supplied into the treating region 120. The second drying gas may be supplied to the treating region 120, and at the same time, the first and second drying gases in the treating region 120 may be discharged to the outside of the treating region 120 through the exhaust member 700. The rate, at which the second drying gas is supplied into the treating region 120, may be the same as the rate, at which the drying gas in the treating region 120 is discharged to the outside of the treating region 120 through the exhaust member 700. In this case, while the second drying gas is supplied to the treating region 120, the pressure inside the treating region 120 may be constantly maintained.

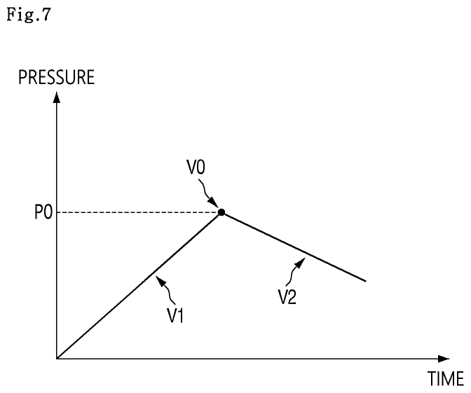

Referring to FIG. 7, the pressure in the treating region 120 may gradually decrease in the second section V2.

In the second section V2, the second drying gas may be supplied into the treating region 120, and at the same time, the drying gas in the treating region 120 may be discharged to the outside of the treating region 120 through the exhaust member 700. When the rate, at which the drying gas in the treating region 120 is discharged to the outside of the treating region 120 through the exhaust member 700, is faster than the rate, at which the second drying gas is supplied into the treating region 120, in the second section V2, the pressure in the treating region 120 may gradually decrease.

However, the technical spirit of the present disclosure is not limited thereto. Contrary to the drawings, in the second section V2, the pressure in the treating region 120 may gradually increase and then be maintained constant, or may be maintained constant and then increased. Also, in the second section V2, the pressure in the treating region 120 may gradually decrease and then be maintained constant, or may be maintained constant and then decreased.

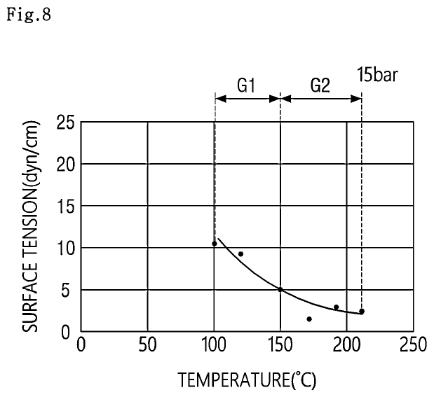

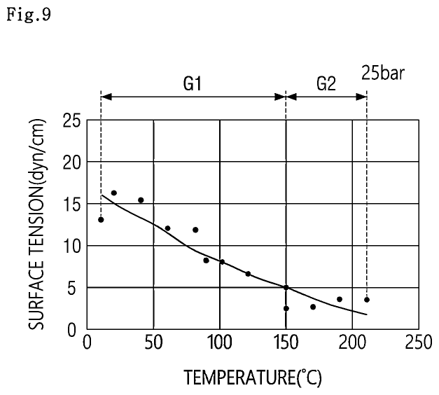

FIGS. 8 and 9 are graphs for describing a drying gas according to some embodiments. For reference, in FIGS. 8 and 9, the X-axis may mean the temperature of the drying gas, and the Y-axis may mean the surface tension between the drying gas and the rinse liquid.

Referring to FIG. 8, under a pressure condition of 15 bar, the drying gas may have a temperature of 100 to 210 degrees. The drying gas having a temperature lower than 150 degrees may have a surface tension between the rinse liquid and the drying gas of greater than 5 dyn/cm. The drying gas having a temperature higher than 150 degrees may have a surface tension between the rinse liquid and the drying gas of less than 5 dyn/cm. Here, the drying gas having a temperature lower than 150 degrees may be the first drying gas G1, and the drying gas having a temperature higher than 150 degrees may be the second drying gas G2.

Referring to FIG. 9, under a pressure condition of 25 bar, the drying gas may have a temperature of 10 degrees to 210 degrees. The drying gas having a temperature lower than 150 degrees may have a surface tension between the rinse liquid and the drying gas of greater than 5 dyn/cm. The drying gas having a temperature higher than 150 degrees may have a surface tension between the rinse liquid and the drying gas of less than 5 dyn/cm. Here, the drying gas having a temperature lower than 150 degrees may be the first drying gas G1, and the drying gas having a temperature higher than 150 degrees may be the second drying gas G2.

In other words, in the first drying gas G1, the surface tension between the rinse liquid and the drying gas is greater than 5 dyn/cm. In the second drying gas G2, the surface tension between the rinse liquid and the drying gas is less than 5 dyn/cm.

As described above, the conditions of the second drying gas G2 for drying the rinse liquid remaining on the substrate may be similar to those of supercritical carbon dioxide. The surface tension between the rinse liquid and supercritical carbon dioxide is less than 5 dyn/cm. Accordingly, a section, in which the surface tension between the rinse liquid and the drying gas is less than 5 dyn/cm, may be a section corresponding to the second drying gas G2. Accordingly, drying the rinse liquid remaining on the substrate S using the second drying gas G2 may obtain an effect similar to drying the rinse liquid using supercritical carbon dioxide.

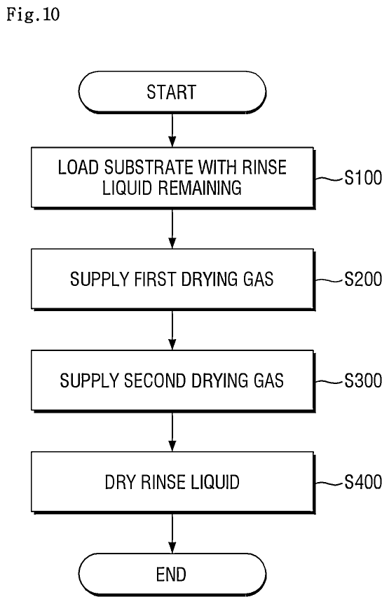

Hereinafter, a substrate treating method according to some embodiments will be described with reference to FIGS. 10 to 15. FIG. 10 is a flowchart illustrating a substrate treating method according to some embodiments.

Referring to FIGS. 2 and 10, in the substrate treating method according to some embodiments, the substrate S, on which the rinse liquid remains, is loaded into the chamber 100 (S100), and a first drying gas is supplied into the chamber 100 (S200). And, second drying gas is supplied into the chamber 100 when the pressure in the chamber 100 reaches a preset pressure (S300), and the rinse liquid on the substrate S is dried (S400).

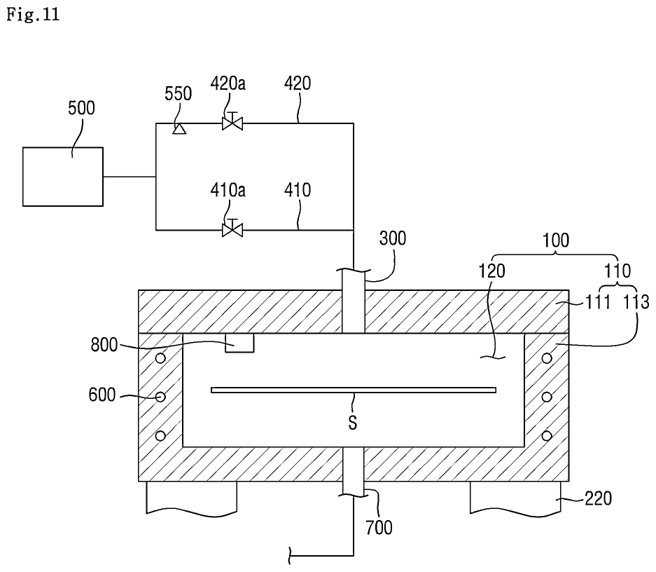

FIG. 11 is an exemplary diagram for describing step S100 of FIG. 10.

Referring to FIG. 11, the substrate S may be loaded into the chamber 100 (S100).

Although not shown, the upper housing 111 and the lower housing 113 may be spaced apart from each other. Subsequently, the substrate S may be loaded into the treating region 120. At this time, the substrate S may be in a state, in which the rinse liquid remains. Subsequently, the lower housing 113 may be lifted to be coupled to the upper housing 111. The treating region 120 may be sealed.

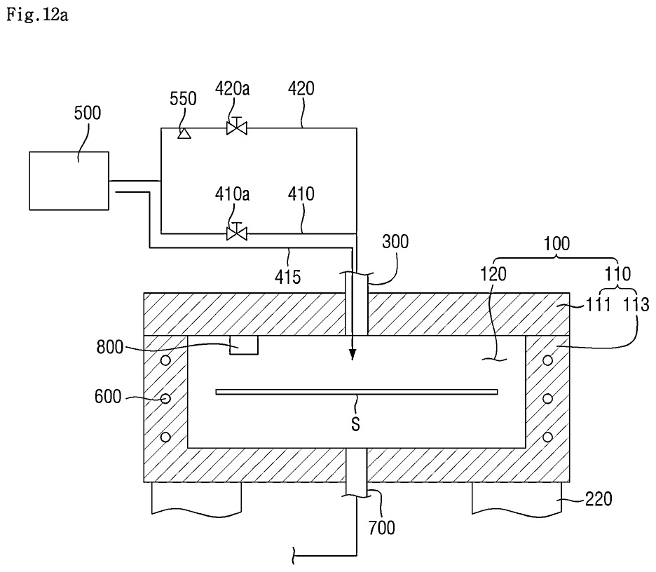

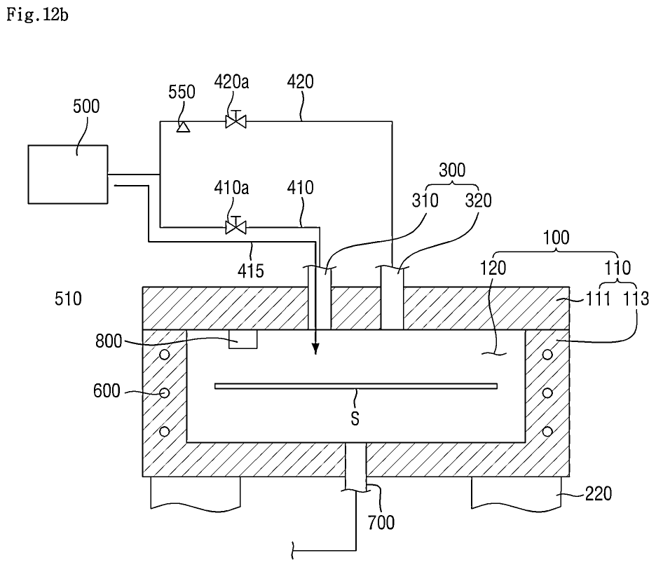

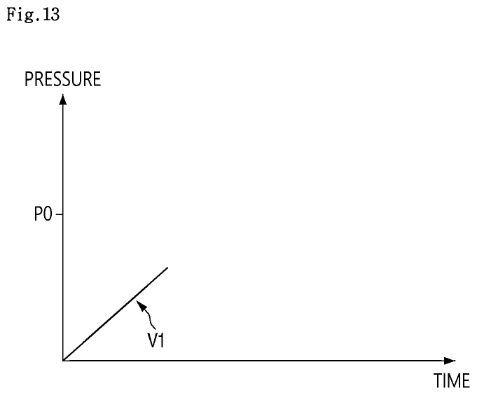

FIGS. 12a to 13 are exemplary views for describing step S200 of FIG. 10.

Referring to 12a and 12b, a first drying gas may be supplied to the treating region 120 (see reference numeral 415). The first drying gas may be supplied through the first supply line 410. The first drying gas is stored in the storage unit 500, and is moved through the first supply line 410 when the first supply valve 410a is opened.

In FIG. 12a, only one supply port 300 is installed in the upper housing 111, and is connected to the first supply line 410 and the second supply line 420. The first drying gas is supplied to the treating region 120 through a supply port 300 via a first supply line 410.

In FIG. 12b, the supply port 300 includes a first supply port 310 and a second supply port 320 installed in the upper housing 111. The first supply port 310 is connected to the first supply line 410. The first drying gas is supplied to the treating region 120 through the first supply line 410 and the first supply port 310.

In FIG. 13, a first section V1 is a section, in which the first drying gas is supplied to the treating region 120. In the first section V1, the pressure in the treating region 120 may be gradually increased.

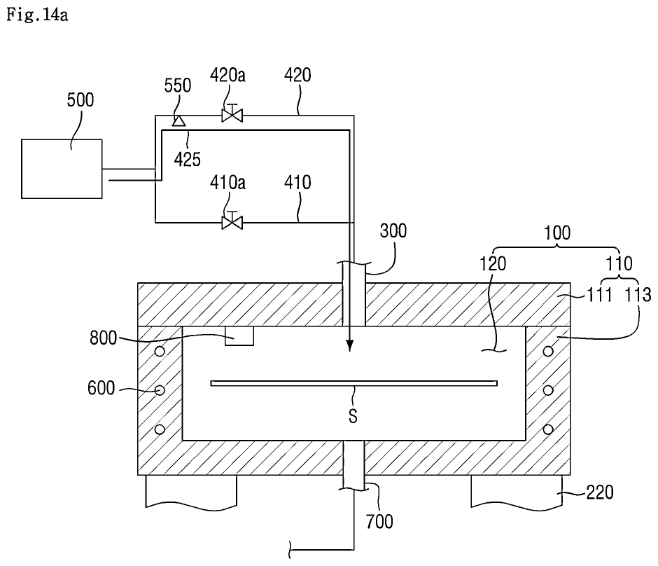

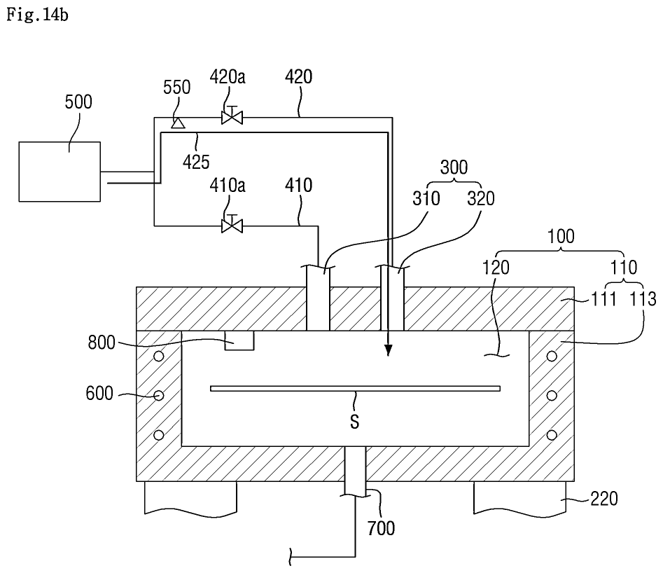

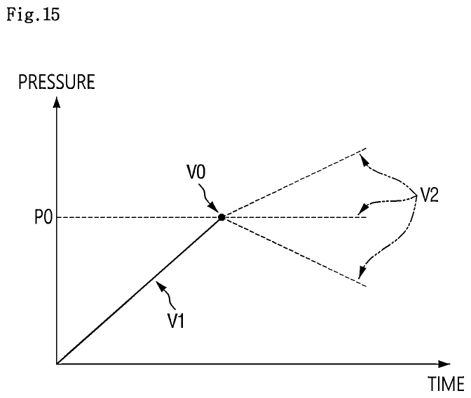

FIGS. 14a to 15 are exemplary views for describing steps S300 and S400 of FIG. 10.

Referring to FIGS. 14a to 15, a second drying gas may be supplied to the treating region 120 (see reference numeral 425). The second drying gas may be supplied through the second supply line 420. The second drying gas is stored in the storage unit 500, and is moved through the second supply line 420 when the second supply valve 420a is opened. The second drying gas may be heated to a first temperature or higher using the heating member 550 installed in the second supply line 420.

In FIG. 14a, only one supply port 300 is installed in the upper housing 111, and is connected to the first supply line 410 and the second supply line 420. The second drying gas is supplied to the treating region 120 through the supply port 300 via the second supply line 420.

In FIG. 14b, the supply port 300 includes a first supply port 310 and a second supply port 320 installed in the upper housing 111. The second supply port 320 is connected to the second supply line 420. The second drying gas is supplied to the treating region 120 through the second supply line 420 and the second supply port 320.

In FIG. 15, a first section V1 is a section, in which the first drying gas is supplied to the treating region 120. In the first section V1, the pressure in the treating region 120 may be gradually increased. When the pressure in the treating region 120 reaches the preset pressure P0, the first section V1 may end and the second section V2 may start (V0). The second section V2 is a section, in which the second drying gas is supplied to the treating region 120. As the second drying gas is supplied to the treating region 120, the pressure in the treating region 120 may increase, decrease, or maintain constant.

Subsequently, the rinse liquid remaining on the substrate may be dried using the second drying gas (S400). The second drying gas is a carbon dioxide gas having a surface tension between the rinse liquid and the second drying gas of 5 dyn/cm or less. Conditions of the second drying gas may be similar to those of supercritical carbon dioxide to effectively dry the rinse liquid.

If the substrate treating apparatus according to some embodiments of the present disclosure is used, the drying process may be more safely performed under a lower pressure condition.

Although embodiments of the present disclosure have been described with reference to the above and the accompanying drawings, those skilled in the art, to which the present disclosure pertains, can understand that the present disclosure may be practiced in other specific forms without changing its technical spirit or essential features. Therefore, it should be understood that the embodiments described above are illustrative in all respects and not limiting.

What is claimed is:

1. An apparatus for treating a substrate comprising:
a chamber including a housing and a treating region, wherein a substrate on which a rinse liquid remains is loaded into the chamber;
a supply port installed in the housing and for supplying a first drying gas and a second drying gas to the treating region;
a first supply line connected to the supply port, and through which the first drying gas is moved; and
a second supply line connected to the supply port, and through which the second drying gas is moved,
wherein the first drying gas is a gas below a first temperature, and the second drying gas is a gas equal to or above the first temperature,
wherein the second drying gas dries the rinse liquid remaining on the substrate.

2. The apparatus of claim 1, wherein the first drying gas is supplied to the treating region in response to a pressure in the treating region being lower than a preset pressure,
wherein the second drying gas is supplied to the treating region in response to a pressure in the treating region being equal to or greater than the preset pressure.

3. The apparatus of claim 2, wherein the preset pressure is 10 bar or more and 40 bar or less.

4. The apparatus of claim 1, wherein the first drying gas does not dry the rinse liquid.

5. The apparatus of claim 1, wherein the first temperature is 150 degrees or more and 250 degrees or less.

6. The apparatus of claim 1, wherein a surface tension between the rinse liquid and the first drying gas is greater than 5 dyn/cm,
wherein a surface tension between the rinse liquid and the second drying gas is 5 dyn/cm or less.

7. The apparatus of claim 1, wherein the supply port comprises a first supply port connected to the first supply line, and a second supply port connected to the second supply line,
wherein the first drying gas is supplied to the treating region through the first supply port,
wherein the second drying gas is supplied to the treating region through the second supply port.

8. The apparatus of claim 1 further comprises,
a storage unit connected to the first supply line and the second supply line; and
a heating member installed in the second supply line and for increasing a temperature of the second drying gas.

9. An apparatus for treating a substrate comprising:
a chamber including a housing and a treating region, wherein a substrate on which a rinse liquid remains is loaded into the chamber;
a supply port installed in the housing and for supplying a first drying gas and a second drying gas that are in a gaseous state to the treating region;
a first supply line connected to the supply port, and through which the first drying gas is moved; and
a second supply line connected to the supply port, and through which the second drying gas is moved,
wherein a surface tension between the rinse liquid and the first drying gas is greater than 5 dyn/cm, and a surface tension between the rinse liquid and the second drying gas is less than 5 dyn/cm.

10. The apparatus of claim 9, wherein the first drying gas is supplied until a pressure in the treating region reaches a preset pressure;
wherein the second drying gas is supplied in response to the pressure in the treating region reaching the preset pressure.

11. The apparatus of claim 10, wherein the preset pressure is 10 bar or more and 40 bar or less.

12. The apparatus of claim 9, wherein the rinse liquid applied on the substrate is dried by using the second drying gas.

13. The apparatus of claim 9, wherein the first drying gas is a CO₂ gas that is less than a first temperature,
wherein the second drying gas is a CO₂ gas that is higher than the first temperature.

14. The apparatus of claim 9, wherein the supply port comprises a first supply port connected to the first supply line, and a second supply port connected to the second supply line,
wherein the first drying gas is supplied to the treating region through the first supply port,
wherein the second drying gas is supplied to the treating region through the second supply port.

15. The apparatus of claim 9 further comprises,
a storage unit connected to the first supply line and the second supply line; and
a heating member installed in the second supply line and for increasing a temperature of the second drying gas.

16. The apparatus of claim 15,
wherein the storage unit comprises a first storage unit connected to the first supply line and for storing the first drying gas, and a second storage unit connected to the second supply line and for storing the second drying gas.

17. A method for treating a substrate comprising:
loading a substrate with a rinse liquid remaining into a chamber;
supplying a first drying gas into the chamber to increase a pressure in the chamber;
stopping the supply of the first drying gas, and supplying a second drying gas different from the first drying gas in response to the pressure in the chamber reaching a preset pressure; and
drying the rinse liquid on the substrate using the second drying gas,
wherein the second drying gas is a gas having a temperature of 150 degrees or more and 250 degrees or less,
wherein a surface tension between the rinse liquid and the second drying gas is 5 dyn/cm or less.

18. The method of claim 17, wherein the preset pressure is 10 bar or more and 40 bar or less.

19. The method of claim 17, wherein the first drying gas is a gas of less than 150° C.,
wherein a surface tension between the first drying gas and the rinse liquid is greater than 5 dyn/cm.

20. The method of claim 17, wherein the first drying gas is supplied into the chamber through a first supply port,
wherein the second drying gas is supplied into the chamber through a second supply port different from the first supply port.
